(19) United States
(12) Patent Application Publication
(10) Pub. No.: US 2026/0173495 A1
(43) Pub. Date: Jun. 18, 2026

(54) METHOD OF MANUFACTURING SEMICONDUCTOR DEVICE

(71) Applicant: SAMSUNG ELECTRONICS CO., LTD., Suwon-si (KR)

(72) Inventor: Jeong Ho MUN, Suwon-si (KR)

(73) Assignee: SAMSUNG ELECTRONICS CO., LTD., Suwon-si (KR)

(21) Appl. No.: 19/380,396

(22) Filed: Nov. 5, 2025

(30) Foreign Application Priority Data
Dec. 18, 2024 (KR) 10-2024-0190456

(51) Int. Cl. H10D 84/01; H10D 84/83

(52) U.S. Cl. CPC H10D 84/014; H10D 84/83135; H10D 84/832

(57) ABSTRACT

Provided is a method of manufacturing a semiconductor device including forming a plurality of first semiconductor patterns in a first active region and a plurality of second semiconductor patterns in a second active region, forming a conductive layer on the plurality of first semiconductor patterns and the plurality of second semiconductor patterns, forming a first organic material layer on the conductive layer, forming a first organic material pattern, removing a portion of the conductive layer to form a sacrificial pattern and a first work function metal layer, forming a second organic material layer on the plurality of first semiconductor patterns, the sacrificial pattern, and the first organic material pattern, performing a heat treatment process to form a second organic material pattern and a crosslinking layer, removing the second organic material pattern to expose the sacrificial pattern, and removing the sacrificial pattern.

### CROSS-REFERENCE TO RELATED APPLICATION

This application claims priority to Korean Patent Application No. 10-2024-0190456, filed on Dec. 18, 2024, in the Korean Intellectual Property Office, the disclosure of which is incorporated by reference herein in its entirety.

### BACKGROUND

Embodiments of the present disclosure relate to a method of manufacturing a semiconductor device, and more particularly, to a method of manufacturing a semiconductor device including a transistor having a multi-gate structure.

Due to the development of electronic technologies, demands for high integration of integrated circuit devices is increasing, and downscaling of integrated circuit devices is in progress. According to the downscaling of integrated circuit devices, there is a risk that the reliability of integrated circuit devices deteriorates due to the occurrence of short channel effects in transistors. To reduce the short-channel effects, integrated circuit devices having a multi-gate structure, such as nanosheet-type transistors, have been proposed.

### SUMMARY

One or more embodiments provide a method of manufacturing a semiconductor device having improved structural reliability.

According to an aspect of one or more embodiments, there is provided a method of manufacturing a semiconductor device, the method including forming a plurality of first semiconductor patterns spaced apart from each other in a vertical direction in a first active region on a substrate and a plurality of second semiconductor patterns spaced apart from each other in the vertical direction in a second active region on the substrate, forming a conductive layer on the plurality of first semiconductor patterns and the plurality of second semiconductor patterns, forming a first organic material layer on the conductive layer, forming a first organic material pattern exposing the first active region from the first organic material layer, removing a portion of the conductive layer using the first organic material pattern to form a sacrificial pattern in the first active region and a first work function metal layer in the second active region, forming a second organic material layer on the plurality of first semiconductor patterns, the sacrificial pattern, and the first organic material pattern, performing a heat treatment process to form a second organic material pattern and a crosslinking layer between the first organic material pattern and the second organic material pattern from the second organic material layer, removing the second organic material pattern to expose the sacrificial pattern, and removing the sacrificial pattern using the crosslinking layer, wherein the first organic material pattern includes a first polymer, a first crosslinker, and a second crosslinker, and the second organic material layer includes a second polymer, and wherein the crosslinking layer is formed by crosslinking the second polymer of the second organic material layer and the second crosslinker of the first organic material pattern.

According to another aspect of one or more embodiments, there is provided a method of manufacturing a semiconductor device, the method including forming a plurality of first semiconductor patterns spaced apart from each other in a vertical direction in a first active region on a substrate and a plurality of second semiconductor patterns spaced apart from each other in the vertical direction in a second active region on the substrate, forming a conductive layer on the plurality of first semiconductor patterns and the plurality of second semiconductor patterns, forming a first organic material layer on the conductive layer and including a first polymer, a first crosslinker, and a second crosslinker, heat-treating the first organic material layer to crosslink the first polymer and the first crosslinker, forming a first organic material pattern exposing the first active region from the heat-treated first organic material layer, removing a portion of the conductive layer using the first organic material pattern to form a sacrificial pattern in the first active region and a first work function metal layer in the second active region, forming a second organic material layer on the plurality of first semiconductor patterns, the sacrificial pattern, and the first organic material pattern, the second organic material layer including a second polymer, performing a heat treatment process to form a second organic material pattern and a crosslinking layer between the first organic material pattern and the second organic material pattern from the second organic material layer, removing the second organic material pattern to expose the sacrificial pattern, and removing the sacrificial layer using the crosslinking layer, wherein the crosslinking layer is formed by crosslinking the second polymer on the second organic material layer and the second crosslinker of the first organic material pattern.

According to still another aspect of one or more embodiments, there is provided a method of manufacturing a semiconductor device, the method including forming a plurality of first semiconductor patterns spaced apart from each other in a vertical direction in a first active region on a substrate and a plurality of second semiconductor patterns spaced apart from each other in the vertical direction in a second active region on the substrate, forming a gate insulating layer on the plurality of first semiconductor patterns and the plurality of second semiconductor patterns, forming a conductive layer on the gate insulating layer, forming a first organic material layer on the conductive layer and including a first polymer, a first crosslinker, and a second crosslinker, performing a first heat treatment process to crosslink the first polymer of the first organic material layer and the first crosslinker, forming a first organic material pattern exposing the first active region from the first organic material layer obtained by the first heat treatment process, removing a portion of the conductive layer using the first organic material pattern to form a sacrificial pattern in the first active region and a first work function metal layer in the second active region, forming a second organic material layer on the plurality of first semiconductor patterns, the sacrificial pattern, and the first organic material pattern, the second organic material layer including a second polymer, performing a second heat treatment process to form a second organic material pattern and a crosslinking layer between the first organic material pattern and the second organic material pattern from the second organic material layer, removing the second organic material pattern to expose the sacrificial pattern, removing the sacrificial layer using the crosslinking layer, removing the crosslinking layer and the first organic material pattern and forming a second work function metal layer on the gate insulating layer and the first work function metal layer, and sequentially forming a gate electrode layer and a gate capping layer on the second work function metal layer, wherein the second organic material layer is formed by crosslinking the second polymer of the second organic material layer with the second crosslinker diffused into the second organic material layer from the first organic material pattern by the second heat treatment process.

According to still another aspect of one or more embodiments, there is provided a semiconductor device including a substrate including a first active region and a second active region, a plurality of first semiconductor patterns spaced apart from each other in a vertical direction in the first active region on the substrate and a plurality of second semiconductor patterns spaced apart from each other in the vertical direction in the second active region on the substrate, a conductive layer on the plurality of first semiconductor patterns and the plurality of second semiconductor patterns, a first organic material layer on the conductive layer, a first organic material pattern exposing the first active region from the first organic material layer, a sacrificial pattern in the first active region and a first work function metal layer in the second active region, a second organic material layer on the plurality of first semiconductor patterns, the sacrificial pattern, and the first organic material pattern, a second organic material pattern and a crosslinking layer between the first organic material pattern and the second organic material pattern, wherein the first organic material pattern includes a first polymer, a first crosslinker, and a second crosslinker, and the second organic material layer includes a second polymer, and wherein the crosslinking layer is formed by crosslinking the second polymer of the second organic material layer and the second crosslinker of the first organic material pattern.

### BRIEF DESCRIPTION OF DRAWINGS

Embodiments will be more clearly understood from the following detailed description taken in conjunction with the accompanying drawings in which:

FIG. 1 is a plan view schematically illustrating a semiconductor device according to one or more embodiments;

FIG. 2A is a cross-sectional view taken along the line X1-X1′ of FIG. 1;

FIG. 2B is a cross-sectional view taken along the lines Y1-Y1′ and Y2-Y2′ of FIG. 1; and

FIGS. 3A, 3B, 4A, 4B, 5, 6, 7A, 7B, 8A, 8B, 9A, 9B, 10, 11, 12, 13, 14, 15, 16, 17, and 18 are cross-sectional views illustrating each step of a method of manufacturing a semiconductor device according to one or more embodiments.

### DETAILED DESCRIPTION

Hereinafter, embodiments will be described in detail with reference to the attached drawings. The same reference symbols are used for identical components in the drawings, and duplicate descriptions of these are omitted. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

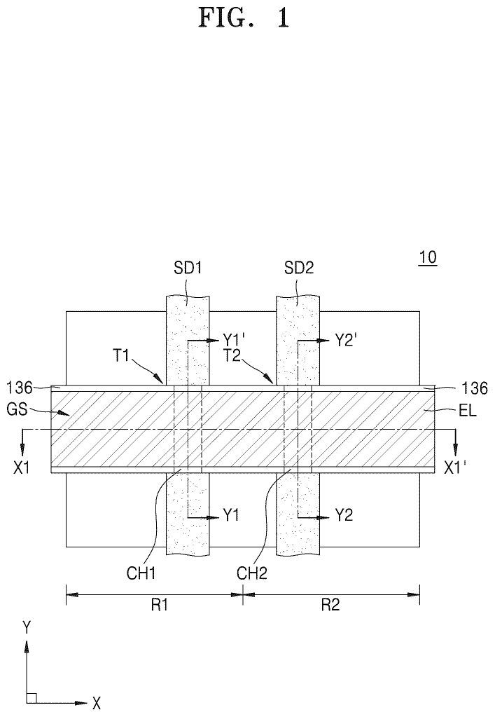

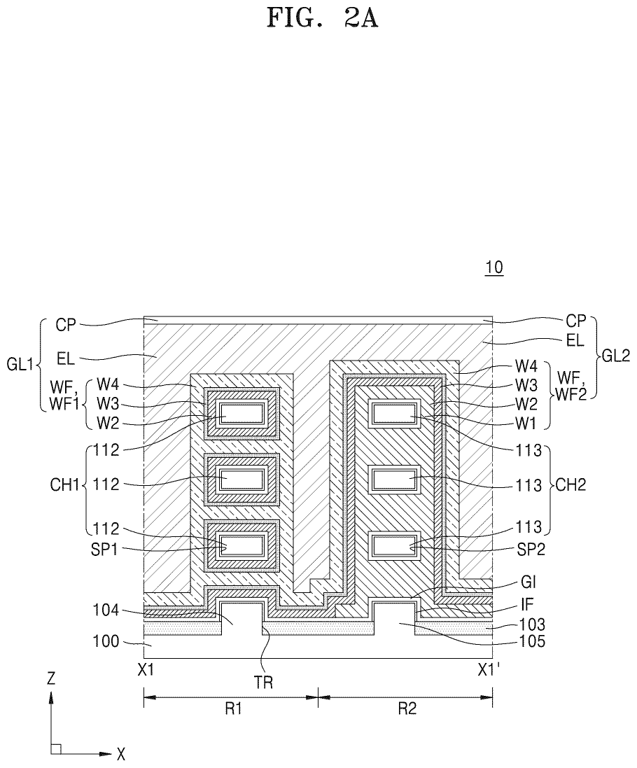

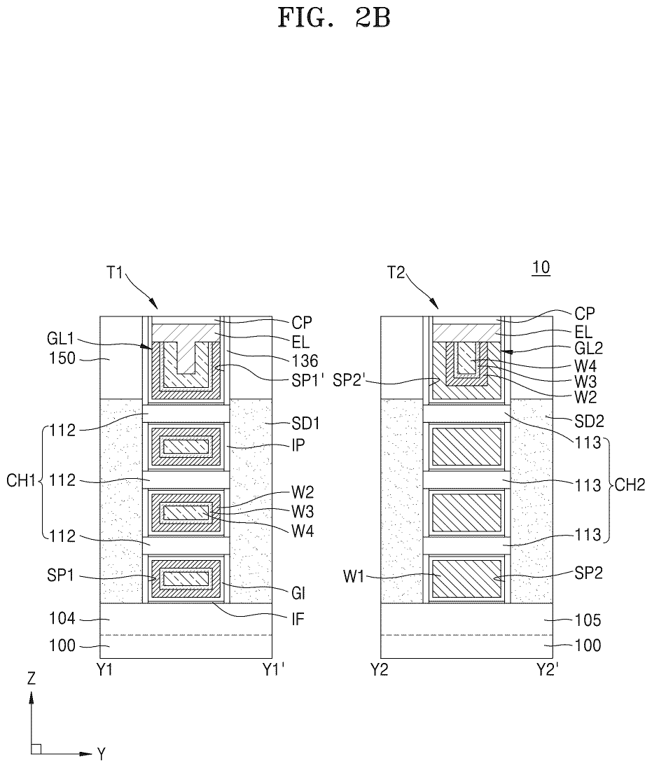

FIG. 1 is a plan view schematically illustrating a semiconductor device 10 according to one or more embodiments. FIG. 2A is a cross-sectional view taken along the line X1-X1′ of FIG. 1. FIG. 2B is a cross-sectional view taken along the lines Y1-Y1′ and Y2-Y2′ of FIG. 1.

Referring to FIG. 1, FIG. 2A, and FIG. 2B, a semiconductor device 10 may include a substrate 100 including a first active region R1 and a second active region R2.

The substrate 100 may include a semiconductor such as silicon (Si) or germanium (Ge), or a compound semiconductor such as silicon germanium (SiGe), silicon carbide (SiC), gallium arsenide (GaAs), indium arsenide (InAs), or indium phosphide (InP).

In one or more embodiments, the substrate 100 may have a semiconductor on insulator (SOI) structure such as, for example, a silicon on insulator structure. The substrate 100 may include a conductive region, for example, a well doped with an impurity or a structure doped with an impurity.

On the substrate 100, the first active region R1 and the second active region R2 may be arranged planarly adjacent to each other in a first horizontal direction (X direction). The first active region R1 and the second active region R2 may each extend in a second horizontal direction (Y direction) perpendicular to the first horizontal direction (X direction).

The first active region R1 and the second active region R2 may have different conductive types from each other. In one or more embodiments, the first active region R1 may be a P-type doped region in which an NMOS is formed, and the second active region R2 may be an N-type doped region in which a PMOS is formed.

An element isolation layer 103 may be placed on the substrate 100. The element isolation layer 103 may define a first upper pattern 104 and a second upper pattern 105 that protrude upward from the substrate 100. For example, the element isolation layer 103 may include an oxide.

The first upper pattern 104 may be placed in the first active region R1, and the second upper pattern 105 may be placed in the second active region R2. The first upper pattern 104 and the second upper pattern 105 may have a pin shape protruding from the upper surface of the substrate 100. The element isolation layer 103 may fill trenches TR at both sides of each of the first upper pattern 104 and the second upper pattern 105. The upper surface of the element isolation layer 103 may be located at a level lower than a level of the upper surface of each of the first upper pattern 104 and the second upper pattern 105 in a vertical direction (Z direction) that is perpendicular to the first horizontal direction (X direction) and the second horizontal direction (Y direction).

A first channel pattern CH1 and a first source/drain region SD1 may be arranged on the first upper pattern 104. A second channel pattern CH2 and a second source/drain region SD2 may be arranged on the second upper pattern 105. The first channel pattern CH1 may overlap the first upper pattern 104 in the vertical direction (Z direction), and the second channel pattern CH2 may overlap the second upper pattern 105 in the vertical direction (Z direction). A pair of first source/drain regions SD1 may be spaced apart from each other in the second horizontal direction (Y direction) with the first channel pattern CH1 therebetween. A pair of second source/drain regions SD2 may be spaced apart from each other in the second horizontal direction (Y direction) with the second channel pattern CH2 therebetween.

The first channel pattern CH1 may include a plurality of first semiconductor patterns 112 that are spaced apart from each other in the vertical direction (Z direction). The plurality of first semiconductor patterns 112 may extend in the second horizontal direction (Y direction). The plurality of first semiconductor patterns 112 may overlap each other in the vertical direction (Z direction). The both sidewalls of each of the first semiconductor patterns 112 may be in contact with the sidewalls of each of a pair of first source/drain regions SD1 spaced apart from each other in the second horizontal direction (Y direction) with the first channel pattern CH1 therebetween. FIGS. 2A and 2B illustrate that the first channel pattern CH1 includes three first semiconductor patterns 112 spaced apart from each other in the vertical direction (Z direction), but embodiments are not limited thereto.

The second channel pattern CH2 may include a plurality of second semiconductor patterns 113 that are spaced apart from each other in the vertical direction (Z direction). The plurality of second semiconductor patterns 113 may extend in the second horizontal direction (Y direction). The plurality of second semiconductor patterns 113 may overlap each other in the vertical direction (Z direction). Both sidewalls of each of the second semiconductor patterns 113 may be in contact with the sidewalls of each of a pair of second source/drain regions SD2 spaced apart from each other in the second horizontal direction (Y direction) with the second channel pattern CH2 therebetween. FIGS. 2A and 2B illustrate that the second channel pattern CH2 includes three second semiconductor patterns 113 spaced apart from each other in the vertical direction (Z direction), but embodiments are not limited thereto.

In one or more embodiments, the plurality of first semiconductor patterns 112 may have the same thicknesses as each other in the vertical direction (Z direction). However, embodiments are not limited thereto, and in one or more other embodiments, the plurality of first semiconductor patterns 112 may have different thicknesses from each other. In embodiments, the plurality of second semiconductor patterns 113 may have the same thicknesses as each other. In other embodiments, the plurality of second semiconductor patterns 113 may have different thicknesses from each other. In one or more embodiments, each of the plurality of first semiconductor patterns 112 and each of the plurality of second semiconductor patterns 113 may have the same thicknesses as each other. In one or more other embodiments, each of the plurality of first semiconductor patterns 112 and each of the plurality of second semiconductor patterns 113 may have different thicknesses from each other.

In one or more embodiments, each of the plurality of first semiconductor patterns 112 and each of the plurality of second semiconductor patterns 113 may include at least one of Si, SiGe, and Ge. In one or more embodiments, each of the plurality of first semiconductor patterns 112 and each of the plurality of second semiconductor patterns 113 may include the same materials as each other. For example, each of the plurality of first semiconductor patterns 112 and each of the plurality of second semiconductor patterns 113 may include SiGe. In one or more other embodiments, each of the plurality of first semiconductor patterns 112 and each of the plurality of second semiconductor patterns 113 may include different materials from each other. For example, each of the plurality of first semiconductor patterns 112 may include SiGe, and each of the plurality of second semiconductor patterns 113 may include Si.

The first source/drain region SD1 may be an epitaxial growth layer formed using the first semiconductor patterns 112 and the first upper pattern 104 as seed layers. The second source/drain region SD2 may be an epitaxial growth layer formed using the second semiconductor patterns 113 and the second upper pattern 105 as seed layers.

The first source/drain region SD1 and the second source/drain region SD2 may each be a region doped with an impurity. For example, the first source/drain region SD1 may be a region doped with an N-type impurity, and the second source/drain region SD2 may be a region doped with a P-type impurity.

A gate structure GS may be placed over the substrate 100. The gate structure GS may extend in the first horizontal direction (X direction). The gate structure GS may include a first gate line GL1, a second gate line GL2, an interface layer IF, a gate insulating layer G1, a first gate spacer IP, and a second gate spacer 136.

The first gate line GL1 may be placed in the first active region R1, and the second gate line GL2 may be placed in the second active region R2. The first gate line GL1 may be provided on and/or cover the first upper pattern 104 and the plurality of first semiconductor patterns 112, and the second gate line GL2 may be provided on and/or cover the second upper pattern 105 and the plurality of second semiconductor patterns 113.

The first gate line GL1 may include a first work function control metal layer WF1, a gate electrode layer EL, and a gate capping layer CP. The second gate line GL2 may include a different number of second work function control layers WF2 from the first work function control metal layer WF1, a gate electrode layer EL, and a gate capping layer CP. The first work function control metal layer WF1 and the second work function control metal layer WF2 may be collectively referred to as a work function control metal layer (WF).

The first work function control metal layer WF1 may be provided on and/or cover the first semiconductor patterns 112 and the first upper pattern 104 in the first active region R1. The second work function control metal layer WF2 may be provided on and/or cover the second semiconductor patterns 113 and the second upper pattern 105 in the second active region R2.

The first work function control metal layer WF1 may include a second work function metal layer W2, a third work function metal layer W3, and a fourth work function metal layer W4. The second work function metal layer W2, the third work function metal layer W3, and the fourth work function metal layer W4 included in the first work function control metal layer WF1 may fill first spaces SP1 among the plurality of first semiconductor patterns 112. In addition, the second work function metal layer W2, the third work function metal layer W3, and the fourth work function metal layer W4 included in the first work function control metal layer WF1 may be sequentially arranged in a first upper space SP1′ on an uppermost first semiconductor pattern 112 among the plurality of first semiconductor patterns 112 in the vertical direction (Z direction).

The second work function control metal layer WF2 may include a first work function metal layer W1, a second work function metal layer W2, a third work function metal layer W3, and a fourth work function metal layer W4. The first work function metal layer W1, the second work function metal layer W2, the third work function metal layer W3, and the fourth work function metal layer W4 included in the second work function control metal layer WF2 may fill second spaces SP2 among the plurality of second semiconductor patterns 113. In addition, the first work function metal layer W1, the second work function metal layer W2, the third work function metal layer W3, and the fourth work function metal layer W4 included in the second work function control metal layer WF2 may be sequentially arranged in a second upper space SP2′ on an uppermost second semiconductor pattern 113 among the plurality of second semiconductor patterns 113 in the vertical direction (Z direction).

The fourth work function metal layer W4 included in the first work function control metal layer WF1 and the fourth work function metal layer W4 included in the second work function control metal layer WF2 may be connected to each other.

Each of the first work function metal layer W1, the second work function metal layer W2, the third work function metal layer W3, and the fourth work function metal layer W4 may include titanium nitride (TiN), titanium carbide (TIC), tantalum nitride (TaN), titanium aluminum carbide (TiAIC), titanium silicon nitride (TiSiN), tantalum carbide (TaC), or a combination thereof. In one or more embodiments, the first work function metal layer W1, the second work function metal layer W2, the third work function metal layer W3, and the fourth work function metal layer W4 may include conductive materials having different work functions from each other.

The gate electrode layer EL may be placed on the work function control metal layer WF. The gate electrode layer EL may extend in the first horizontal direction (X direction). The gate electrode layer EL may include, for example, aluminum (Al), tungsten (W), titanium (Ti), tantalum (Ta), or a combination thereof.

The gate capping layer CP may be placed on the gate electrode layer EL. The gate capping layer CP may extend in the first horizontal direction (X direction). The gate capping layer CP may include, for example, silicon oxynitride (SiON), silicon carbon nitride (SiCN), silicon carbon oxynitride (SiCON), silicon nitride (SiN), or a combination thereof.

The interface layer IF may be adjacent to and/or surround the first semiconductor patterns 112 of the first channel pattern CH1 and the second semiconductor patterns 113 of the second channel pattern CH2. The interface layer IF may be provided on and/or cover the first upper pattern 104 and the second upper pattern 105 protruding upward from the element isolation layer 103 in the vertical direction (Z direction). The interface layer IF may include, for example, silicon oxide.

The gate insulating layer G1 may be placed between the first semiconductor patterns 112 of the first channel pattern CH1 and the first gate line GL1 and between the second semiconductor patterns 113 of the second channel pattern CH2 and the second gate line GL2. The gate insulating layer G1 may be placed on the interface layer IF. The gate insulating layer G1 may be spaced apart from the first semiconductor patterns 112 and the second semiconductor patterns 113 with the interface layer IF therebetween. The gate insulating layer G1 may be provided on and/or cover the element isolation layer 103.

The gate insulating layer G1 may include, for example, a high-dielectric material having a dielectric constant (k) greater than a dielectric constant of silicon oxide. The high-dielectric material may include, for example, hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), and zirconium oxide (ZrO₂), zirconium silicon oxide (ZrSiO), lanthanum oxide (La₂O₃), lanthanum aluminum oxide (LaAlO₃), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), and lead zinc niobate (PbZnNbO₃), or a combination thereof.

The first gate spacer 136 and the second gate spacer IP may be arranged on both sidewalls of the first gate line GL1 and both sidewalls of the second gate line GL2, respectively. The first gate spacer 136 and the second gate spacer IP may extend in the first horizontal direction (X direction) along the first gate line GL1 and the second gate line GL2, respectively. The first gate spacer 136 may be placed in the first upper space SP1′ and the second upper space SP2′, and the second gate spacer IP may be placed in the first spaces SP1 and the second spaces SP2. The upper surface of the first gate spacer 136 may located be at a level greater than a level of the upper surface of the gate electrode layer EL in the vertical direction (Z direction). The upper surface of the first gate spacer 136 may be coplanar with the upper surface of the gate capping layer CP. Each of the first gate spacer 136 and the second gate spacer IP may include, for example, at least one of SiCN, SiCN, and SiN. In one or more embodiments, each of the first gate spacer 136 and the second gate spacer IP may include a multilayered film.

The first active region R1, the first channel pattern CH1, the first upper pattern 104, the first source/drain region SD1, and the first gate line GL1 may constitute a first transistor T1, and the second active region R2, the second channel pattern CH2, the second upper pattern 105, the second source/drain region SD2, and the second gate line GL2 may constitute a second transistor T2.

The first transistor T1 and the second transistor T2 may be transistors having different threshold voltages from each other. For example, the first transistor T1 may be an NMOS transistor, and the second transistor T2 may be a PMOS transistor.

The first transistor T1 and the second transistor T2 may each be a multi-bridge channel field effect transistor (MBCFET) or a gate-all-around transistor.

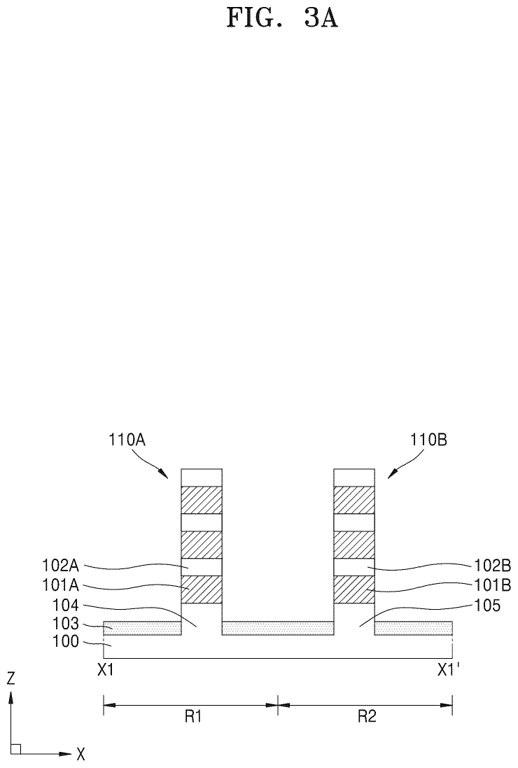

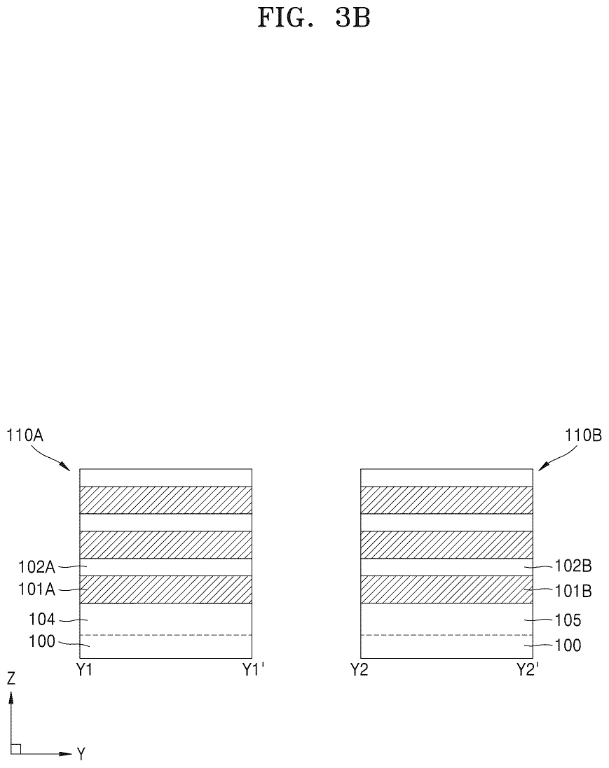

FIGS. 3A, 3B, 4A, 4B, 5, 6, 7A, 7B, 8A, 8B, 9A, 9B, 10, 11, 12, 13, 14, 15, 16, 17, and 18 are cross-sectional views illustrating each step of a method of manufacturing a semiconductor device according to one or more embodiments.

Referring to FIGS. 3A and 3B, sacrificial layers and semiconductor layers may be alternately stacked on a substrate 100, and the substrate 100, the sacrificial layers, and the semiconductor layers may be patterned to form a first preliminary active pattern 110A and a second preliminary active pattern 110B. The upper portion of the substrate 100 may be partially removed by the patterning process, so that the first upper pattern 104 and the second upper pattern 105 may be formed. The first preliminary active pattern 110A may include alternately stacked first sacrificial layers 101A and first semiconductor layers 102A, and the second preliminary active pattern 110B may include alternately stacked second sacrificial layers 101B and second semiconductor layers 102B. Each of the first sacrificial layers 101A and the second sacrificial layers 101B may include a material having an etching selectivity with respect to each of the first semiconductor layers 102A and the second semiconductor layers 102B. For example, the first sacrificial layers 101A and the second sacrificial layers 101B may include SiGe or Ge, and the first semiconductor layers 102A and the second semiconductor layers 102B may include Si.

Each of the first sacrificial layers 101A and the second sacrificial layers 101B and each of the first semiconductor layers 102A and the second semiconductor layers 102B may be formed by an epitaxial growth process using the substrate 100 as a seed layer.

Each of the first preliminary active pattern 110A and the second preliminary active pattern 110B may extend in the second horizontal direction (Y direction).

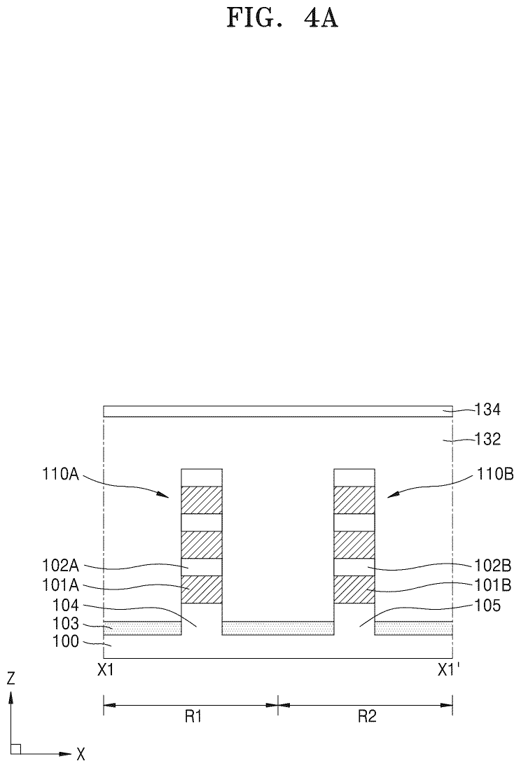

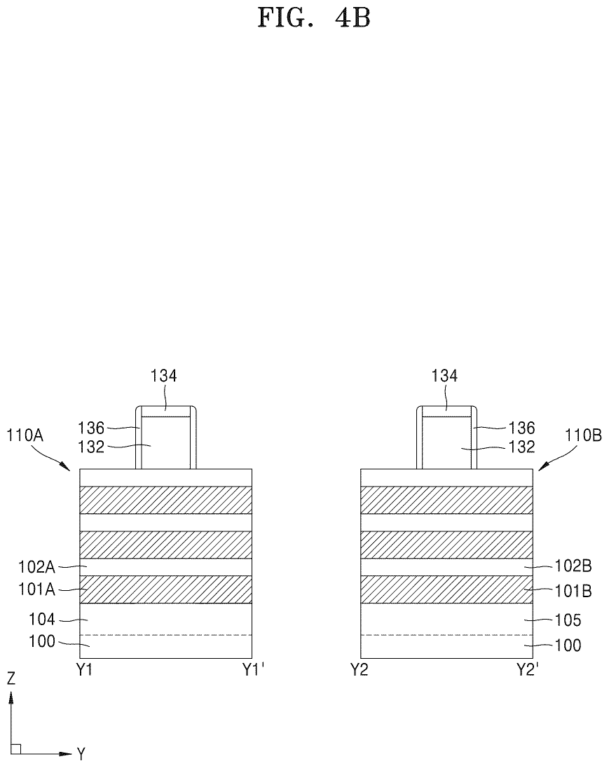

Referring to FIGS. 4A and 4B, a dummy gate line 132 provided on and/or covering the first preliminary active pattern 110A and the second preliminary active pattern 110B, a dummy gate capping layer 134 placed on the dummy gate line 132, and a first gate spacer 136 provided on and/or covering both sidewalls of each of the dummy gate line 132 and the dummy gate capping layer 134 may be formed. For example, the dummy gate line 132 may be formed of polysilicon, and the dummy gate capping layer 134 may be made of a silicon nitride film. The first gate spacer 136 may be formed of, but is not limited to, silicon oxide, silicon oxynitride, or silicon nitride.

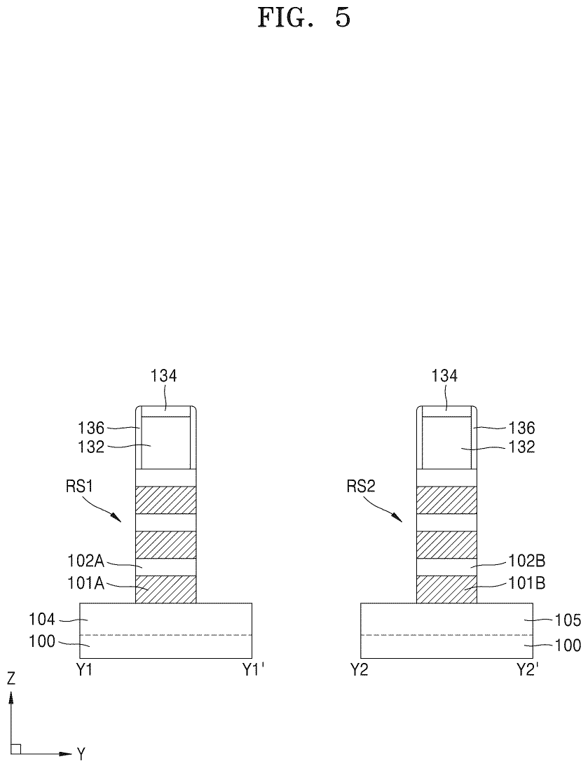

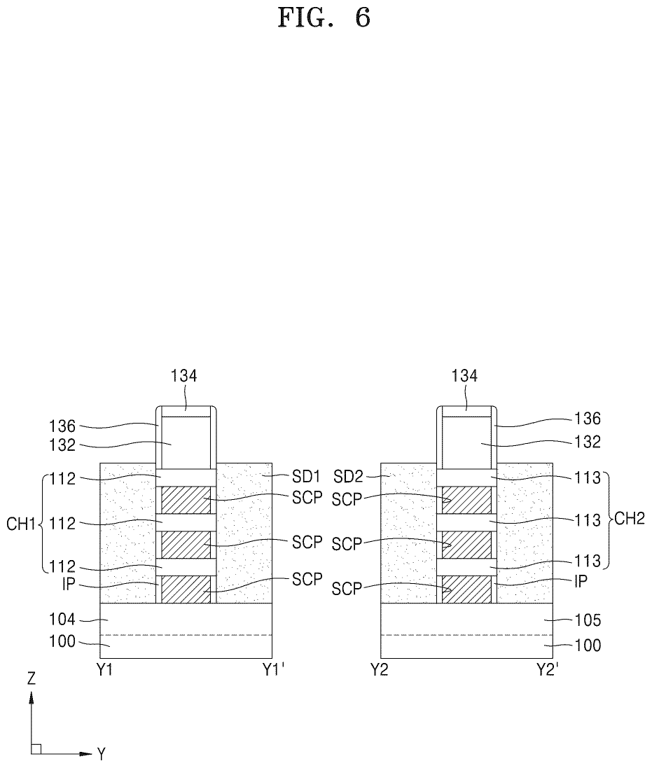

Referring to FIG. 5, the first preliminary active pattern 110A (refer to FIG. 4A) and the second preliminary active pattern 110B (refer to FIG. 4A) may be patterned using the dummy gate line 132, the dummy gate capping layer 134, and the first gate spacer 136 as an etching mask. A portion of the first preliminary active pattern 110A (refer to FIG. 4A) and a portion of the second preliminary active pattern 110B (refer to FIG. 4A) may be removed by the patterning process to form a first recess RS1 and a second recess RS2, respectively. After the process described with reference to FIG. 5 is performed, the first semiconductor layers 102A may be referred to as a first semiconductor pattern 112 (refer to FIG. 6) and the second semiconductor layers 102B may be referred to as a second semiconductor pattern 113 (refer to FIG. 6).

Referring to FIG. 6, a first source/drain region SD1 and a second source/drain region SD2 may be formed in the first recess RS1 (refer to FIG. 5) and the second recess RS2 (refer to FIG. 5), respectively. The first source/drain region SD1 may be formed by performing an epitaxial process using the first semiconductor pattern 112 and the first upper pattern 104 as seed layers, and the second source/drain SD2 region may be formed by performing an epitaxial process using the second semiconductor pattern 113 and the second upper pattern 105 as seed layers.

Next, the first sacrificial layers 101A (refer to FIG. 5) and the second sacrificial layers 101B (refer to FIG. 5) may be partially removed horizontally to form sacrificial patterns SCP. Next, a second gate spacer IP may be formed in the space where the first sacrificial layers 101A (refer to FIG. 5) and the second sacrificial layers 101B (refer to FIG. 5) are removed.

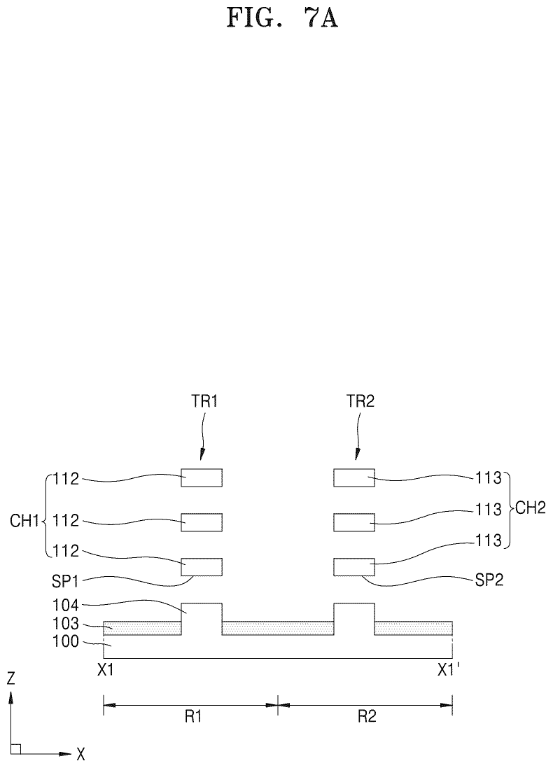

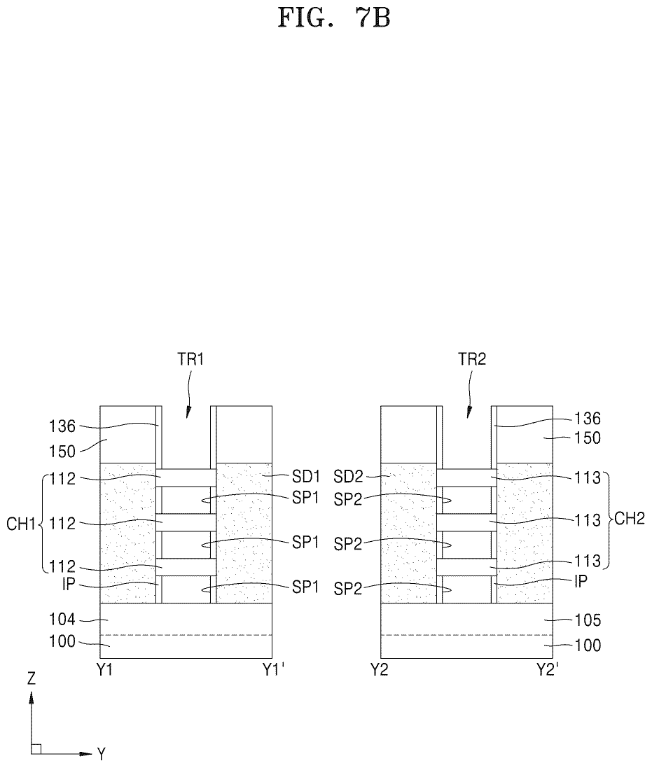

Referring to FIGS. 7A and 7B, the dummy gate capping layer 134 (refer to FIG. 6) and the dummy gate line 132 (refer to FIG. 6) may be removed. By removing the dummy gate capping layer 134 (refer to FIG. 6) and the dummy gate line 132 (refer to FIG. 6), a first trench TR1 may be formed in the first active region R1, and a second trench TR2 may be formed in the second active region R2. The first trench TR1 and the second trench TR2 may communicate with each other. The first trench TR1 may expose the first semiconductor patterns 112, and the second trench TR2 may expose the second semiconductor patterns 113. In addition, the first trench TR1 and the second trench TR2 may expose the sacrificial pattern SCP (refer to FIG. 6).

Next, the sacrificial pattern SCP (refer to FIG. 6) exposed through the first trench TR1 and the second trench TR2 may be removed. When the sacrificial pattern SCP (refer to FIG. 6) is removed, a first space SP1 may be formed in the first active region R1, and the second space SP2 may be formed in the second active region R2. The first space SP1 may communicate with the first trench TR1, and the second space SP2 may communicate with the second trench TR2.

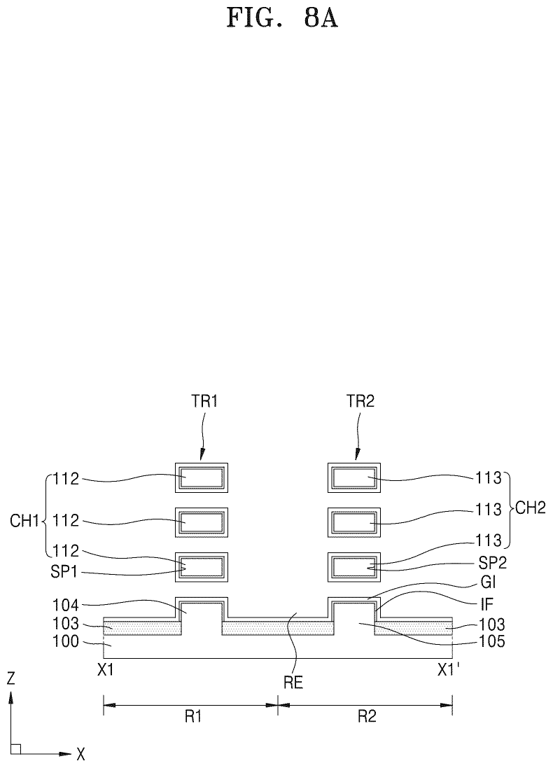

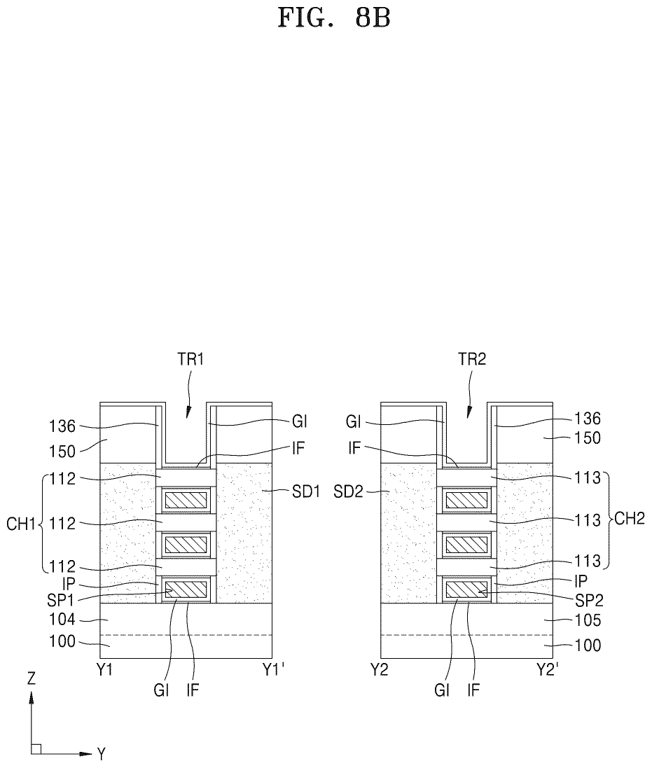

Referring to FIGS. 8A and 8B, an interface layer IF and a gate insulating layer G1 may be sequentially formed within the first trench TR1 and the first space SP1 in the first active region R1, and an interface layer IF and a gate insulating layer G1 may be sequentially formed within the second trench TR2 and the second space SP2 in the second active region R2.

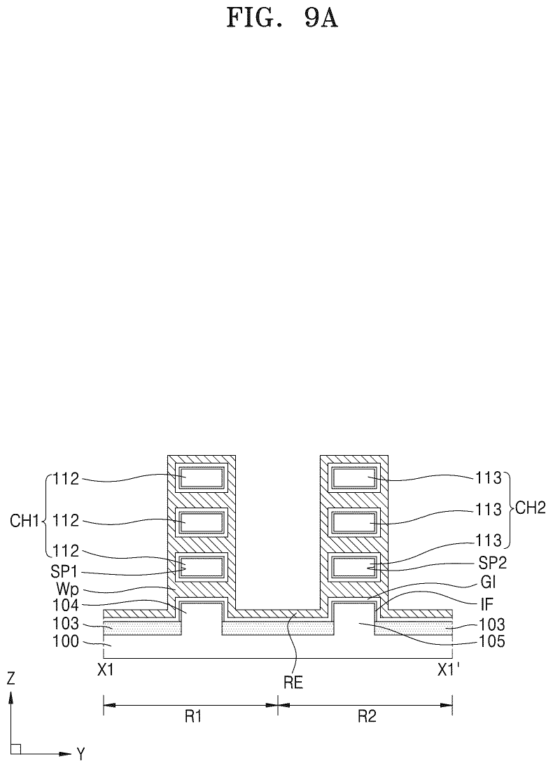

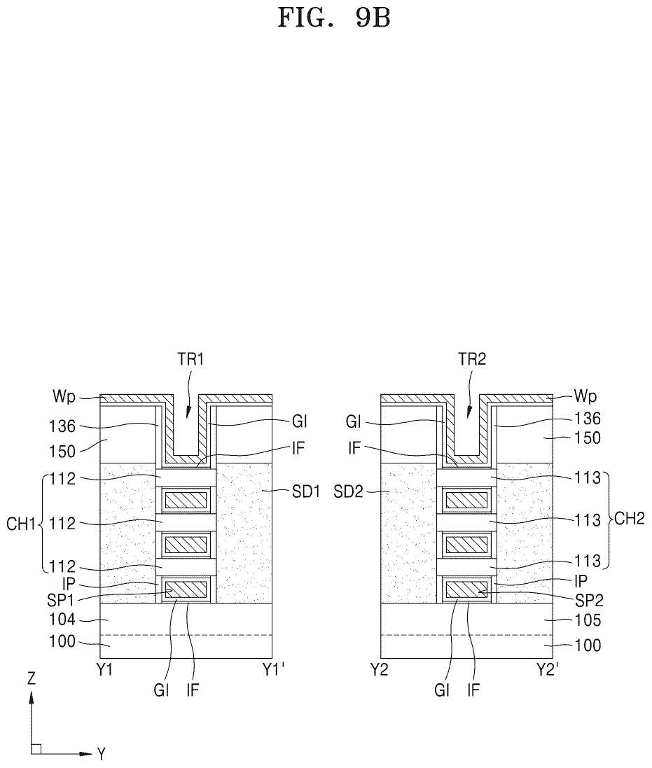

Referring to FIGS. 9A and 9B, a conductive layer Wp may be formed to fill each of the first space SP1 and the second space SP2 and to be provided on and/or cover the gate insulating layer G1 formed in the first trench TR1 and the gate insulating layer G1 formed in the second trench TR2. The conductive layer Wp may be formed through a deposition process such as an atomic layer deposition process. The conductive layer Wp may include, for example, TiN.

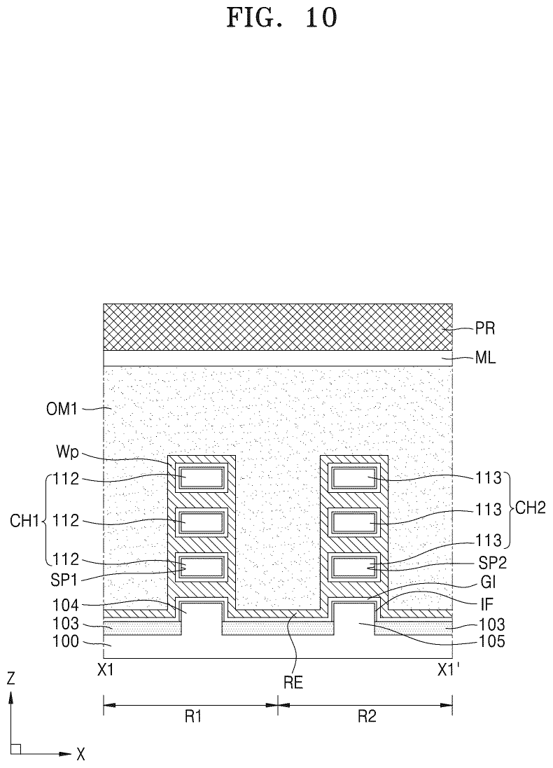

Referring to FIG. 10, a first organic material layer OM1 provided on and/or covering the conductive layer Wp may be formed, and the first organic material layer OM1 may be heat-treated.

The first organic material layer OM1 may include a first polymer, a first crosslinker, and a second crosslinker.

The first polymer may include a copolymer of a first monomer including a functional group capable of crosslinking with the first crosslinker without a separate acid catalyst, and a second monomer including a functional group having etching resistance against a wet etchant. The copolymer may be, for example, a random copolymer of the first monomer and the second monomer, but embodiments are not limited thereto. The ratio of the content of the first monomer included in the first polymer and the content of the second monomer included in the first polymer may be adjusted according to the manufacturing process conditions of a semiconductor device.

The first monomer may include a linear, branched, or cyclic carbon skeleton and a functional group capable of crosslinking with the first crosslinker with a separate acid catalyst, and the second monomer may include a linear, branched, or cyclic carbon skeleton and a functional group having etching resistance against a wet etchant.

In one or more embodiments, the first monomer may be represented by Formula 1-1 below.

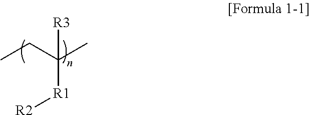

Here, in Formula 1-1, R1 may be a carbonyl group or a phenyl group, R2 may be a hydroxyl group, a thiol group, an amine group, an alkoxy group, an epoxy group, or a carboxyl group, and R3 may be hydrogen, an alkyl group having 1 to 3 carbon atoms, or a fluoroalkyl group having 1 to 3 carbon atoms.

In one or more embodiments, the first monomer may be represented by Formula 1-2 below.

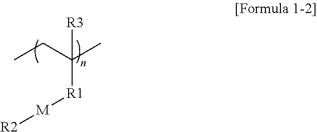

Here, in Formula 1-2, R1 may be a carbonyl group or a phenyl group, R2 may be a hydroxyl group, a thiol group, an amine group, an alkoxy group, an epoxy group, or a carboxyl group, R3 may be hydrogen, an alkyl group having 1 to 3 carbon atoms, a fluoroalkyl group having 1 to 3 carbon atoms, and M may be a straight-chain alkyl group, a branched alkyl group, a cyclic alkyl group, or an aryl group.

The second monomer may be represented by Formula 2 below.

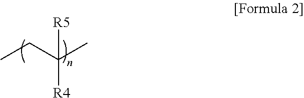

Here, in Formula 2, R4 may be an aromatic compound having 1 to 4 aromatic rings or a polycyclic compound having 4 to 20 carbon atoms, and R5 may be hydrogen, an alkyl group having 1 to 3 carbon atoms, or a fluoroalkyl group having 1 to 3 carbon atoms.

The polycyclic compound having 4 to 20 carbon atoms may be, for example, a polycyclic aliphatic compound having 4 to 20 carbon atoms.

The first crosslinker may include a linear, branched, or cyclic carbon skeleton and a functional group capable of crosslinking with the first monomer without a separate acid catalyst.

In one or more embodiments, the first crosslinker may be represented by Formula 3.

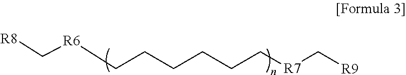

Here, in Formula 3, R6 and R7 may each independently be carbon or a heteroatom, and R8 and R9 may each independently be a hydroxy group, a thiol group, an amine group, an alkoxy group, an epoxy group, or a carboxyl group.

The second crosslinker may include a central molecule and a functional group that is bonded to the central molecule and is capable of crosslinking with a second polymer of a second organic material layer OM2 to be described later without a separate acid catalyst. A molecular weight of the second crosslinker may less than a molecular weight of the first crosslinker.

The central molecule may be a cyclic molecule including a heteroatom. The central molecule may be, for example, glycoluril or melamine.

The functional groups bonded to the central molecule may be, for example, 2 to 6 functional groups. The functional groups may each independently be, for example, a hydroxyl group, a thiol group, an amine group, an alkoxy group, an epoxy group, or a carboxyl group.

In one or more embodiments, the central molecule and the functional groups may be bonded through a carbon atom. In one or more other embodiments, the central molecule and the functional groups may be bonded through a heteroatom such as an oxygen atom.

The heat treatment of the first organic material layer OM1 may be performed at a temperature of about 180° C. to about 300° C. The first polymer of the first organic material layer OM1 and the first crosslinker of the first organic material layer OM1 may be crosslinked by the heat treatment.

Next, a mask layer ML and a photoresist layer PR may be sequentially formed on the heat-treated first organic material layer OM1. The mask layer ML may include a material having an etching selectivity with respect to the first organic material layer OM1. The mask layer ML may include, for example, an oxide.

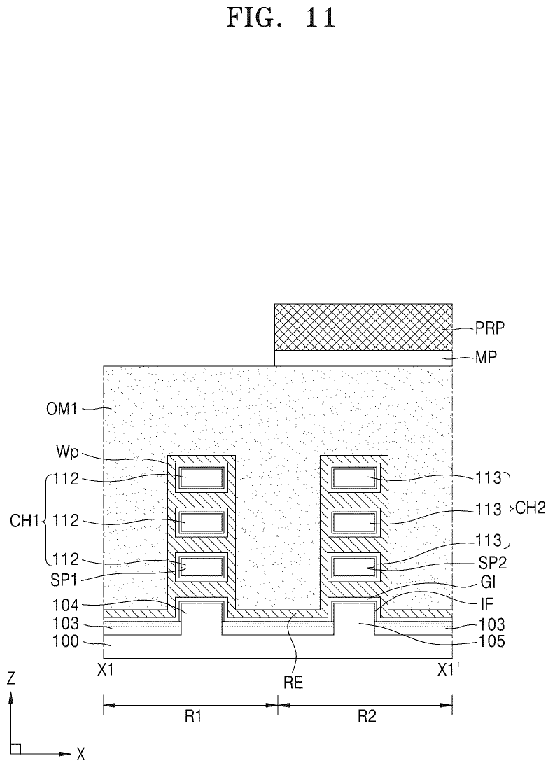

Referring to FIG. 11, a photoresist pattern PRP may be formed by exposing the photoresist layer PR (refer to FIG. 10) to expose the first active region R1. The light source of the exposure process may be a KrF excimer laser (248 nm), an ArF excimer laser (193 nm), an F2 excimer laser (157 nm), or extreme ultraviolet (EUV) laser (13.5 nm), but embodiments are not limited thereto.

Next, a mask pattern MP that exposes the first active region R1 may be formed by patterning the mask layer ML (refer to FIG. 10) using the photoresist pattern PRP as an etching mask.

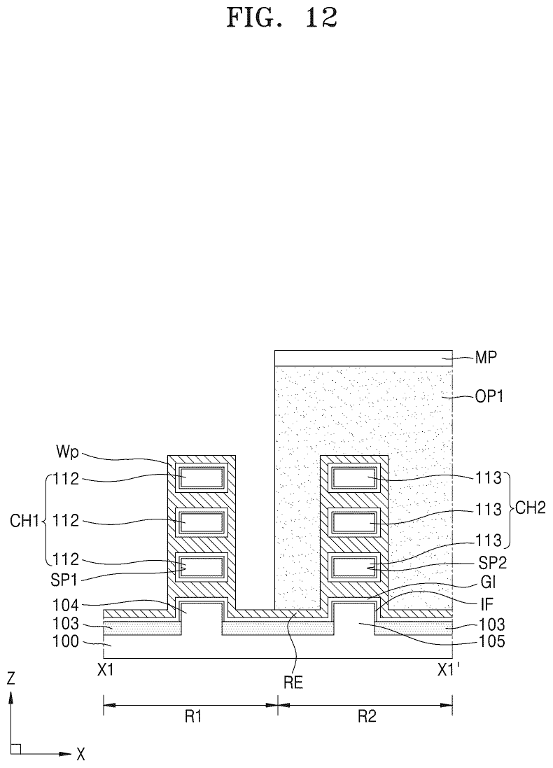

Referring to FIG. 12, the photoresist pattern PRP (refer to FIG. 11) may be removed from the upper surface of the mask pattern MP. The photoresist pattern PRP may be removed, for example, by an ashing process or a stripping process.

Next, a portion of the first organic material layer OM1 (refer to FIG. 10) placed on the first active region R1 exposed by the mask pattern MP may be etched using the mask pattern MP as an etching mask. The etching process may be, for example, a dry etching process. The residual portion of the first organic layer OM1 (refer to FIG. 10) remaining after performing the etching process may be referred to as a first organic material pattern OP1.

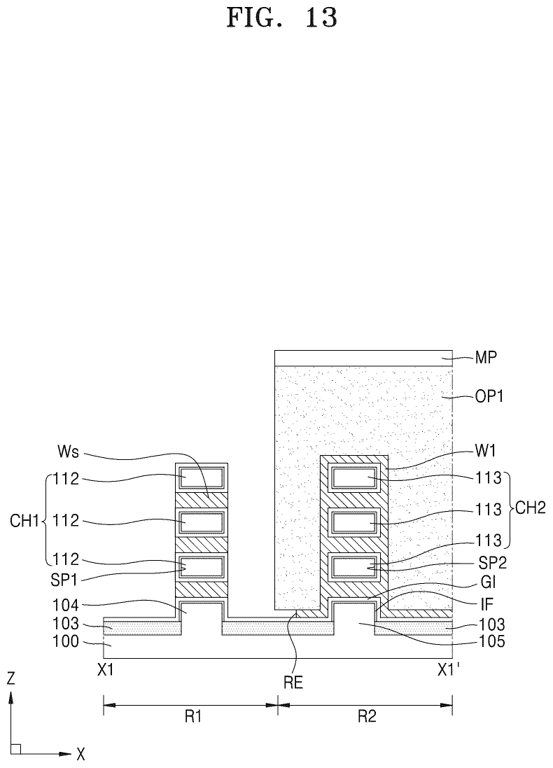

Referring to FIG. 13, a portion of the conductive layer Wp (refer to FIG. 12) in the first active region R1 may be etched using the mask pattern MP as an etching mask. The etching process may be, for example, a wet etching process. After performing the etching process, the residual portion of the conductive layer Wp (refer to FIG. 12) remaining in the first active region R1 may be referred to as a sacrificial pattern Ws, and the conductive layer Wp (refer to FIG. 12) remaining in the second active region R2 may be referred to as a first work function metal layer W1. A sacrificial pattern Ws may be formed by removing the residual portions of the conductive layers Wp (refer to FIG. 12), except for the portions among the plurality of first semiconductor patterns 112 and the portions between the lowermost first semiconductor pattern 112 and the first upper pattern 104.

After the etching process is performed, the first work function metal layer W1 may remain inside and/or under the first organic material pattern OP1. The first work function metal layer W1 and the sacrificial pattern Ws may be separated from each other by the etching process. When a portion of the conductive layer Wp (refer to FIG. 12) in contact with the lower surface of the first organic material pattern OP1 is removed, a recessed region RE may be formed under the first organic material pattern OP1. The recess region RE may be defined by the lower surface of the first organic material pattern OP1, one end of the first work function metal layer W1, and the upper surface of the gate insulating layer G1.

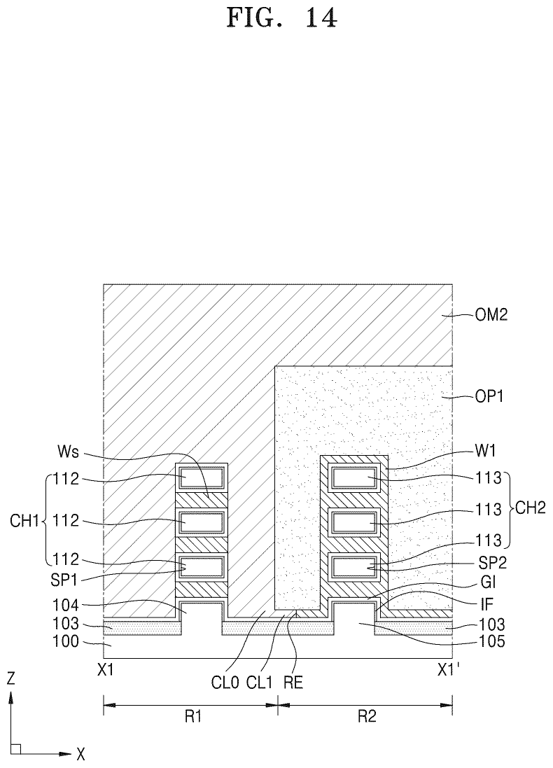

Referring to FIG. 14, a second organic material layer OM2 may be formed in the first active region R1 and the second active region R2. The second organic material layer OM2 may be provided on and/or cover the surfaces of the first channel pattern CH1, the gate insulating layer G1, and the sacrificial pattern Ws in the first active region R1, be provided on and/or cover the first organic material pattern OP1 in the second active region R2, and fill the recess region RE (refer to FIG. 13).

In one or more embodiments, the second organic material layer OM2 may include a second polymer. The second polymer may include a copolymer of a first monomer including a functional group capable of crosslinking with the second crosslinker of the first organic material layer OM1 without a separate acid catalyst, and a second monomer including a functional group having etching resistance against a wet etchant. The copolymer may be, for example, a random copolymer of the first monomer and the second monomer, but embodiments are not limited thereto. The ratio of the content of the first monomer included in the first polymer and the content of the second monomer included in the first polymer may be adjusted according to the manufacturing process conditions of a semiconductor device.

In one or more embodiments, the first monomer of the second polymer may be a component similar to the first monomer of the first polymer of the above-described first organic material layer OM1, and the second monomer of the second polymer may be a component similar to the second monomer of the above-described first organic material layer OM1.

In one or more embodiments, the ratio of the content of the first monomer of the second polymer of the second organic material layer OM2 to the content of the second monomer thereof may be different from the ratio of the content of the first monomer of the first polymer of the first organic material layer OM1 to the content of the second monomer thereof, but embodiments are not limited thereto.

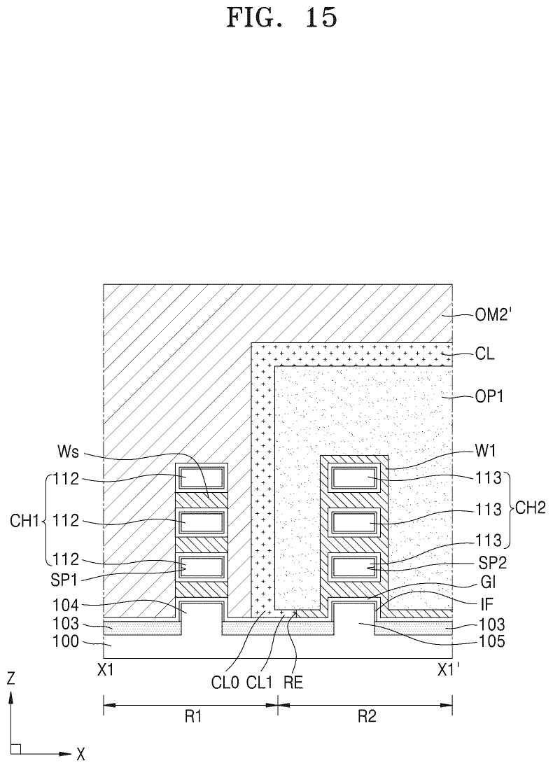

Referring to FIG. 15, the second organic material layer OM2 (refer to FIG. 14) may be heat-treated to crosslink the second polymer of the second organic material layer OM2 (refer to FIG. 14) and the second crosslinker of the first organic material pattern OP1. A crosslinking layer CL may be formed from the second organic material layer OM2 (refer to FIG. 14) by the crosslinking. The crosslinking layer CL may be in contact with the upper surface, side surface, and lower surface of the first organic material pattern OP1, the lower surface thereof being exposed by the recess region RE. The crosslinking layer CL may fill the recess region RE. The crosslinking layer CL may include an inner portion CLI placed within the recess region RE and an outer portion CLO placed outside the recess region RE. The inner side CLI of the crosslinking layer CL may be in contact with the first work function metal layer W1. The second organic material pattern OM2′ may have a thickness of about 3 nm to about 20 nm from the surface of the first organic material pattern OP1 in the vertical direction (Z direction).

The heat treatment process may be performed at about 100° C. to about 240° C. The heat treatment process may be, for example, a soft baking or a post exposure baking (PEB) process.

Through the heat treatment process, the second crosslinker included in the first organic material pattern OP1 may diffuse into the second organic material layer OM2 (refer to FIG. 14), and the diffused second crosslinker may form the crosslinking layer CL by crosslinking with the second polymer of the second organic material layer OM2 (refer to FIG. 14). For example, a portion of the second organic material layer OM2 may be converted into the crosslinking layer CL. In addition, the residual portion of the non-crosslinked second organic material layer OM2 may be referred to as a non-crosslinked second organic material layer pattern OM2′. That is, the crosslinking layer CL may be placed between the first organic material pattern OP1 and the second organic material pattern OM2′. The second organic material pattern OM2′ may be provided on and/or cover the second semiconductor patterns 113, the gate insulating layer G1 surrounding the second semiconductor patterns 113, the sacrificial patterns Ws, and the first organic material pattern OP1. The second organic pattern OM2′ may cover the crosslinking layer CL.

In a related method of manufacturing a semiconductor device using a first organic material layer and a second organic material layer, a crosslinking layer was formed from the second organic material layer using an acid generated from a thermal acid generator as a catalyst. However, when the catalyst is not consumed in the crosslinking and is excessively diffused in the heat treatment process for forming a crosslinking layer, the crosslinking layer may be excessively formed, so that a problem may occur in which a region to be etched in the etching process to be described later is protected by the crosslinking layer and is thus not etched. For example, in a related method of manufacturing a semiconductor device, there is a problem of difficulty in securing a process margin of an etching process.

On the other hand, in the method of manufacturing a semiconductor device 10 according to one or more embodiments, the second crosslinker included in the first organic material pattern OP1 may diffuse into the second organic material layer OM2 (refer to FIG. 14), and the diffused second crosslinker may directly crosslink with the second polymer of the second organic material layer OM2 (refer to FIG. 14), thereby forming the crosslinking layer CL. For example, since the second crosslinker is directly bonded to the second polymer, the second crosslinker is not excessively diffused due to the consumption of the second crosslinker in the crosslinking, so that excessive formation of the crosslinking layer CL can be prevented. Accordingly, the region to be etched in the etching process to be described later can be properly etched, and thus the structural reliability of the semiconductor device 10 can be improved.

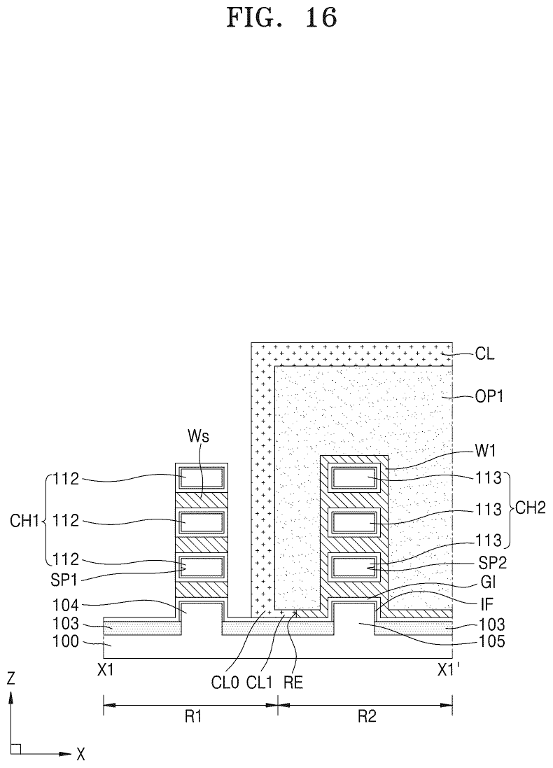

Referring to FIG. 16, the second organic material pattern OM2′ (refer to FIG. 15) may be removed. The second organic material pattern OM2′ may be removed using an organic solvent such as propylene glycol monomethyl ether acetate (PGMEA), propylene glycol monomethyl ether (PGME), methyl 2-hydroxyisobutyrate (HBM), ethyl lactate (EL), ethyl 3-ethoxypropionate (EEP), gamma-butyrolactone (GBL), n-butyl acetate (nBA), or a combination thereof. Since the crosslinking layer CL is in a crosslinked state, the crosslinking layer CL may not be removed even when the process of FIG. 16 is performed.

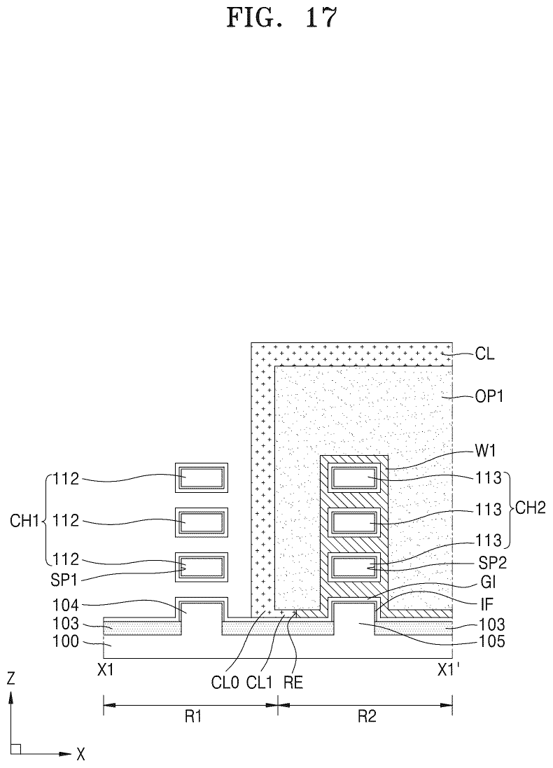

Referring to FIG. 17, the sacrificial pattern Ws (refer to FIG. 16) may be removed using the crosslinking layer CL as an etching mask. The etching process may be, for example, a wet etching process. The etching process may be performed using an etchant having an etching selectivity with respect to the crosslinking layer CL and the gate insulating layer G1. The first spaces SP1 may be emptied by removing the sacrificial pattern Ws (refer to FIG. 16).

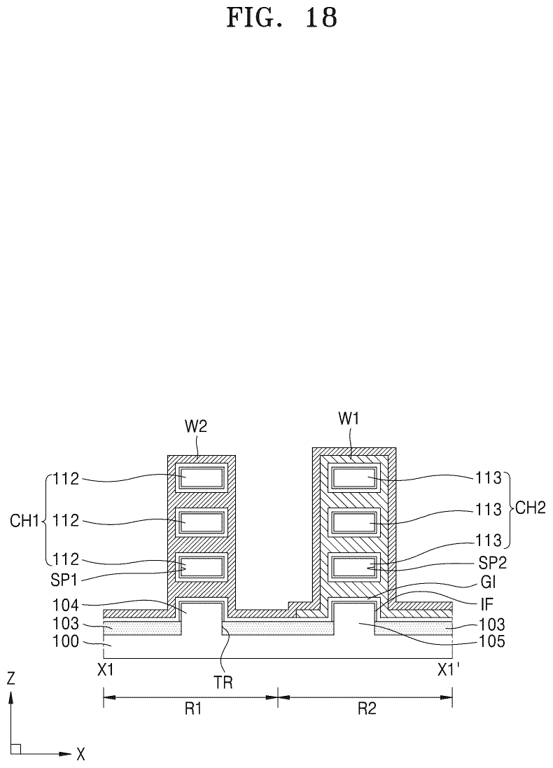

Referring to FIG. 18, the method may include a process of removing the crosslinking layer CL (refer to FIG. 17) and the first organic material pattern OP1 (refer to FIG. 17). The crosslinking layer CL (refer to FIG. 17) and the first organic material pattern OP1 (refer to FIG. 17) may be removed to expose the first work function metal layer W1.

Next, a second work function metal layer W2 provided on and/or covering the first channel pattern CH1 and the first work function metal layer W1 may be formed. The second work function metal layer W2 may fill the first space SP1 between the first channel patterns CH1. The second work function metal layer W2 may have a step at one end of the first work function metal layer W1 located between the first upper pattern 104 and the second upper pattern 105.

Next, from the resultant of FIG. 18, a third work function metal layer W3 and a fourth work function metal layer W4 may be formed on the second work function metal layer W2, and a gate electrode layer GL and a gate capping layer Cp may be formed on the fourth work function metal layer W4, thereby manufacturing the semiconductor device 10 as illustrated in FIGS. 1, 2A, and 2B.

As described above, embodiments have been disclosed in the drawings and specification. Although specific terms have been used to describe embodiments in this specification, they have been used only for the purpose of explaining the technical idea of the present disclosure and are not intended to limit the meaning or the scope of the present disclosure set forth in the claims. Therefore, a person having ordinary skill in the art will understand that various modifications and equivalent other embodiments are possible therefrom. Therefore, the true technical protection scope of the present disclosure should be determined by the technical idea of the appended claims and their equivalents.

While embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing a semiconductor device, the method comprising:
forming a plurality of first semiconductor patterns spaced apart from each other in a vertical direction in a first active region on a substrate and a plurality of second semiconductor patterns spaced apart from each other in the vertical direction in a second active region on the substrate;
forming a conductive layer on the plurality of first semiconductor patterns and the plurality of second semiconductor patterns;
forming a first organic material layer on the conductive layer;
forming a first organic material pattern exposing the first active region from the first organic material layer;
removing a portion of the conductive layer using the first organic material pattern to form a sacrificial pattern in the first active region and a first work function metal layer in the second active region;
forming a second organic material layer on the plurality of first semiconductor patterns, the sacrificial pattern, and the first organic material pattern;
performing a heat treatment process to form a second organic material pattern and a crosslinking layer between the first organic material pattern and the second organic material pattern from the second organic material layer;
removing the second organic material pattern to expose the sacrificial pattern; and
removing the sacrificial pattern using the crosslinking layer,
wherein the first organic material pattern comprises a first polymer, a first crosslinker, and a second crosslinker, and the second organic material layer comprises a second polymer, and
wherein the crosslinking layer is formed by crosslinking the second polymer of the second organic material layer and the second crosslinker of the first organic material pattern.

2. The method of claim 1, wherein the first polymer is a copolymer of a first monomer comprising a linear, branched, or cyclic carbon skeleton and a functional group configured to crosslinked with the first crosslinker without a separate acid catalyst and a second monomer comprising a linear, branched, or cyclic carbon skeleton and a functional group having etching resistance against a wet etchant.

3. The method of claim 2, wherein the first monomer is represented by: 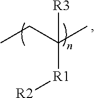
where R1 is a carbonyl group or a phenyl group, R2 is a hydroxy group, a thiol group, an amine group, an alkoxy group, an epoxy group, or a carboxyl group, and R3 is hydrogen, an alkyl group having 1 to 3 carbon atoms, or a fluoroalkyl group having 1 to 3 carbon atoms.

4. The method of claim 2, wherein the first monomer is represented by: 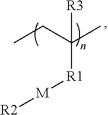
where R1 is a carbonyl group or a phenyl group, R2 is a hydroxyl group, a thiol group, an amine group, an alkoxy group, an epoxy group, or a carboxyl group, R3 is hydrogen, an alkyl group having 1 to 3 carbon atoms, a fluoroalkyl group having 1 to 3 carbon atoms, and M is a linear alkyl group, a branched alkyl group, a cyclic alkyl group, or an aryl group.

5. The method of claim 2, wherein the second monomer is represented by: 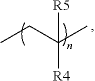
where R4 is an aromatic compound having 1 to 4 aromatic rings or a polycyclic aliphatic compound having 4 to 20 carbon atoms, and R5 is hydrogen, an alkyl group having 1 to 3 carbon atoms, or a fluoroalkyl group having 1 to 3 carbon atoms.

6. The method of claim 2, wherein the first crosslinker comprises a linear, branched, or cyclic carbon skeleton and a functional group capable of crosslinking with the first monomer without a separate acid catalyst.

7. The method of claim 1, wherein the first crosslinker is represented by: 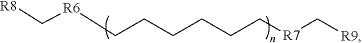
where R6 and R7 are each independently carbon or a heteroatom, and R8 and R9 are each independently a hydroxy group, a thiol group, an amine group, an alkoxy group, an epoxy group, or a carboxyl group.

8. The method of claim 1, wherein the second crosslinker comprises a central molecule and a functional group bonded to the central molecule and configured to be crosslinked with the second polymer of the second organic material layer.

9. The method of claim 1, wherein a molecular weight of the second crosslinker is less than a molecular weight of the first crosslinker.

10. The method of claim 1, wherein the second crosslinker is configured to be diffused into the second organic material layer from the first organic material pattern by the heat treatment process.

11. The method of claim 1, wherein a central molecule of the second crosslinker is a cyclic molecule comprising a heteroatom.

12. The method of claim 1, wherein the second crosslinker has 2 to 6 functional groups bonded to a central molecule, and the functional groups are each independently a hydroxyl group, a thiol group, an amine group, an alkoxy group, an epoxy group, or a carboxyl group.

13. A method of manufacturing a semiconductor device, the method comprising:
forming a plurality of first semiconductor patterns spaced apart from each other in a vertical direction in a first active region on a substrate and a plurality of second semiconductor patterns spaced apart from each other in the vertical direction in a second active region on the substrate;
forming a conductive layer on the plurality of first semiconductor patterns and the plurality of second semiconductor patterns;
forming a first organic material layer on the conductive layer and comprising a first polymer, a first crosslinker, and a second crosslinker;
heat-treating the first organic material layer to crosslink the first polymer and the first crosslinker;
forming a first organic material pattern exposing the first active region from the heat-treated first organic material layer;
removing a portion of the conductive layer using the first organic material pattern to form a sacrificial pattern in the first active region and a first work function metal layer in the second active region;
forming a second organic material layer on the plurality of first semiconductor patterns, the sacrificial pattern, and the first organic material pattern, the second organic material layer comprising a second polymer;
performing a heat treatment process to form a second organic material pattern and a crosslinking layer between the first organic material pattern and the second organic material pattern from the second organic material layer;
removing the second organic material pattern to expose the sacrificial pattern; and
removing the sacrificial layer using the crosslinking layer,
wherein the crosslinking layer is formed by crosslinking the second polymer on the second organic material layer and the second crosslinker of the first organic material pattern.

14. The method of claim 13, wherein the first polymer is a copolymer of a first monomer comprising a linear, branched, or cyclic carbon skeleton and a functional group configured to be crosslinked with the first crosslinker without a separate acid catalyst and a second monomer including a linear, branched, or cyclic carbon skeleton and a functional group having etching resistance against a wet etchant.

15. The method of claim 14, wherein the second polymer is a copolymer of a first monomer comprising a linear, branched, or cyclic carbon skeleton and a functional group configured to be crosslinked with the second crosslinker without a separate acid catalyst and a second monomer including a linear, branched, or cyclic carbon skeleton and a functional group having etching resistance against a wet etchant.

16. The method of claim 15, wherein a ratio of content of the first monomer of the first polymer and content of the second monomer of the first polymer is different from a ratio of content of the first monomer of the second polymer and content of the second monomer of the second polymer.

17. The method of claim 14, wherein the first crosslinker comprises a linear, branched, or cyclic carbon skeleton and a functional group configured to be crosslinked with the first monomer without a separate acid catalyst, and
wherein the second crosslinker comprises a central molecule and a functional group bonded to the central molecule and configured to be crosslinked with the second polymer of the second organic material layer.

18. A method of manufacturing a semiconductor device, the method comprising:
forming a plurality of first semiconductor patterns spaced apart from each other in a vertical direction in a first active region on a substrate and a plurality of second semiconductor patterns spaced apart from each other in the vertical direction in a second active region on the substrate;
forming a gate insulating layer on the plurality of first semiconductor patterns and the plurality of second semiconductor patterns;
forming a conductive layer on the gate insulating layer;
forming a first organic material layer on the conductive layer and including a first polymer, a first crosslinker, and a second crosslinker;
performing a first heat treatment process to crosslink the first polymer of the first organic material layer and the first crosslinker;
forming a first organic material pattern exposing the first active region from the first organic material layer obtained by the first heat treatment process;
removing a portion of the conductive layer using the first organic material pattern to form a sacrificial pattern in the first active region and a first work function metal layer in the second active region;
forming a second organic material layer on the plurality of first semiconductor patterns, the sacrificial pattern, and the first organic material pattern, the second organic material layer comprising a second polymer;
performing a second heat treatment process to form a second organic material pattern and a crosslinking layer between the first organic material pattern and the second organic material pattern from the second organic material layer;
removing the second organic material pattern to expose the sacrificial pattern;
removing the sacrificial layer using the crosslinking layer;
removing the crosslinking layer and the first organic material pattern and forming a second work function metal layer on the gate insulating layer and the first work function metal layer; and
sequentially forming a gate electrode layer and a gate capping layer on the second work function metal layer,
wherein the second organic material layer is formed by crosslinking the second polymer of the second organic material layer with the second crosslinker diffused into the second organic material layer from the first organic material pattern by the second heat treatment process.

19. The method of claim 18, wherein the crosslinking layer has a thickness of 3 nm to 20 nm.

20. The method of claim 18, wherein the first heat treatment process is performed at 180° C. to 300° C., and the second heat treatment process is performed at 100° C. to 240° C.
